(19) United States
(12) Patent Application Publication
(10) Pub. No.: US 2026/0029451 A1
(43) Pub. Date: Jan. 29, 2026

(54) NOISE AND JITTER COMPENSATION AND SIGNAL PROCESSING OF EQUIVALENT-TIME WAVEFORMS

(71) Applicant: KEYSIGHT TECHNOLOGIES, INC., SANTA ROSA, CA (US)

(72) Inventors: Marlin E. Viss, Santa Rosa, CA (US); Ryan Chodora, SANTA ROSA, CA (US)

(21) Appl. No.: 19/349,136

(22) Filed: Oct. 3, 2025

Related U.S. Application Data
(63) Continuation-in-part of application No. 18/383,921, filed on Oct. 26, 2023.

(51) Int. Cl. G01R 29/26; G01R 1/28; G01R 13/02; G06N 7/04

(52) U.S. Cl. CPC G01R 29/26; G01R 1/28; G01R 13/0218; G06N 7/04

(57) ABSTRACT

A digital signal processing method is for enhancing fidelity of equivalent-time waveform measurements. The method includes receiving a digitized equivalent-time waveform of a repeating signal under test (SUT), applying a low-pass filter to the digitized equivalent-time waveform to obtain a smoothed waveform, generating a residual waveform by subtracting the smoothed waveform from the digitized equivalent-time waveform, estimating contributions of multiple noise sources in the residual waveform using a regression model, computing target noise and jitter values by removing known intrinsic contributions, and reconstructing a corrected waveform by combining the smoothed waveform with a scaled version of the residual waveform, wherein the scaling is based on the target noise source contributions.

### CROSS-REFERENCE TO RELATED APPLICATION(S)

This is a continuation-in-part (CIP) of U.S. patent application Ser. No. 18/383,921, filed Oct. 26, 2023, in the U.S. Patent and Trademark Office, the disclosure of which is incorporated by reference herein in its entirety.

### FIELD

The present disclosure relates to digital signal processing of equivalent-time waveforms, and more particularly to methods for compensating noise and jitter in equivalent-time sampling systems while preserving signal-dependent noise characteristics.

### BACKGROUND

Equivalent-time sampling is a technique used in signal acquisition and measurement systems to reconstruct high-frequency waveforms using lower-speed sampling hardware. This method operates by sampling a repetitive signal over multiple trigger events, allowing the capture of signals with frequencies much higher than the sampling rate of the acquisition system.

In equivalent-time sampling systems, the reconstructed waveform can be affected by various sources of distortion. These distortions include uncorrelated noise, which manifests as vertical scatter due to random amplitude fluctuations, and uncorrelated jitter, which introduces horizontal smearing around signal transitions due to timing uncertainty in the sampling process.

The nature of noise in these systems can vary. Some noise sources, such as additive white Gaussian noise, affect the signal uniformly across all amplitude levels. Other noise types, like relative intensity noise (RIN) in laser-based systems, have an impact that is proportional to the instantaneous signal level, resulting in more pronounced distortion at higher signal amplitudes.

These distortions present challenges in waveform signal processing applications. For instance, when applying virtual equalization to an equivalent-time waveform, it is desirable for the resulting processed waveform to accurately represent not only the deterministic shape of the signal but also the correct noise and jitter characteristics.

Existing techniques for noise removal in equivalent-time sampling systems often struggle to address the complexities introduced by non-uniform noise distributions and jitter effects. This can lead to inaccuracies in signal analysis and interpretation, particularly in applications requiring high precision and fidelity.

### SUMMARY

According to an aspect of the inventive concepts, a digital signal processing method for enhancing fidelity of equivalent-time waveform measurements is provided. The method includes receiving a digitized equivalent-time waveform of a repeating signal under test (SUT), applying a low-pass filter to the digitized equivalent-time waveform to obtain a smoothed waveform, generating a residual waveform by subtracting the smoothed waveform from the digitized equivalent-time waveform, estimating contributions of multiple noise sources in the residual waveform using a regression model, computing target noise

$$( {σ}_{n}^{target} )$$

and jitter

$$( {σ}_{j}^{target} )$$

values by removing known intrinsic contributions, and reconstructing a corrected waveform by combining the smoothed waveform with a scaled version of the residual waveform, wherein the scaling is based on the target noise source contributions.

Estimating contributions of multiple noise sources may include calculating a time derivative of the smoothed waveform, constructing a regression model relating the residual waveform to the smoothed waveform and its derivative, and solving the regression model to estimate parameters corresponding to additive noise, jitter-induced noise, and relative intensity noise. The regression model may be of the form:

$${R ( t )}^{2} \approx {σ}_{n}^{2} + {σ}_{j}^{2} {D ( t )}^{2} + {σ}_{l}^{2} {S ( t )}^{2}$$

where R(t) is the residual waveform, D(t) is the derivative of the smoothed waveform, S(t) is the smoothed waveform, σₙ represents additive noise, σⱼ represents jitter-induced noise, and σₗ represents relative intensity noise. Solving the regression model may include normalizing D(t) and S(t) to unit maximums, performing least-squares linear regression to determine coefficients β₀, β₁, and β₂, and extracting standard deviations σₙ, σⱼ, and σₗ from the coefficients.

Reconstructing the corrected waveform may include computing a time-varying scaling factor α(t) based on the target noise source contributions, and applying the scaling factor to the residual waveform before combining it with the smoothed waveform. The method may further include applying additional filtering to the smoothed waveform to produce a filtered waveform, calculating a derivative of the filtered waveform, and computing a new scaling factor based on the filtered waveform and its derivative. Reconstructing the corrected waveform may further include combining the filtered waveform with the residual waveform scaled by the new scaling factor to produce a filtered and corrected waveform.

According to another aspect of the inventive concepts, a system for digital signal processing of equivalent-time waveforms is provided. The system includes an input interface configured to receive a digitized equivalent-time waveform of a repeating signal under test (SUT), and a processor configured to apply a low-pass filter to the digitized equivalent-time waveform to obtain a smoothed waveform, calculate a residual waveform by subtracting the smoothed waveform from the digitized equivalent-time waveform, estimate contributions of multiple noise sources in the residual waveform using a regression model, and reconstruct a corrected waveform by combining the smoothed waveform with a scaled version of the residual waveform, wherein the scaling is based on the estimated noise source contributions. The system further includes an output interface configured to output the corrected waveform.

According to still another aspect of the inventive concepts, a non-transitory computer-readable medium is provided storing instructions that, when executed by a processor, cause the processor to perform digital signal processing operations for enhancing fidelity of equivalent-time waveform measurements. The digital signal processing operations include receiving a digitized equivalent-time waveform of a repeating signal under test (SUT), applying a low-pass filter to the digitized equivalent-time waveform to obtain a smoothed waveform, generating a residual waveform by subtracting the smoothed waveform from the digitized equivalent-time waveform, estimating contributions of multiple noise sources in the residual waveform using a regression model, and reconstructing a corrected waveform by combining the smoothed waveform with a scaled version of the residual waveform, wherein the scaling is based on the estimated noise source contributions.

### BRIEF DESCRIPTION OF THE DRAWINGS

The above and other aspects and features of the inventive concepts will become readily apparent from the detailed description that follows, with reference to the accompanying drawings, in which:

FIG. 1 illustrates examples of signal waveforms for reference in describing the effects of noise and jitter on equivalent-time waveforms;

FIG. 2 illustrates examples of signal waveforms for reference in describing the effects of relative intensity noise (RIN) on equivalent-time waveforms;

FIG. 3 is a simplified block diagram of a test system for making measurements of a signal under test (SUT), according to a representative embodiment; and

FIGS. 4 through 7 are flow diagrams for reference in describing methods for enhancing the fidelity of equivalent-time waveform measurements according to embodiments of the inventive concepts.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skills in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for the purpose of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

The drawings may in some cases focus on structural features of embodiments of the inventive concepts. However, the drawings may not be drawn to scale, and relative dimensions of different structural elements may differ from those depicted in the drawings. Further, throughout the drawings, like reference numbers refer to the same or similar elements.

As is traditional in the field of the inventive concepts, embodiments may be described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

The technology underlying the inventive concepts is directed to a digital signal processing method and architecture for enhancing the fidelity of equivalent-time waveform measurements. In current equivalent-time sampling systems, waveforms are reconstructed by sampling a repetitive signal over multiple trigger events. When noise and jitter are uncorrelated to the trigger signal, they manifest as distinct distortions in the reconstructed waveform. Uncorrelated noise appears as vertical scatter due to random amplitude fluctuations, while uncorrelated jitter introduces horizontal smearing around signal transitions due to timing uncertainty in the sampling process. Noise may be simple additive noise, or it may be proportional to the instantaneous signal level such as for laser relative intensity noise (RIN).

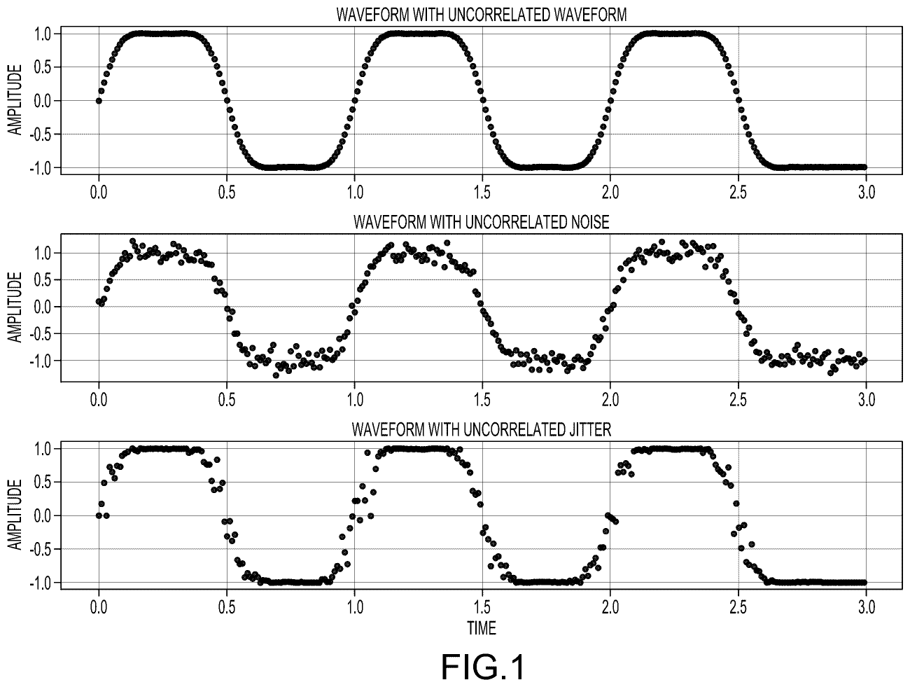

FIG. 1 illustrates examples of signal waveforms for reference in describing the effects of noise and jitter on equivalent-time waveforms. The top plot illustrates an equivalent-time sampled version of an ideal band-limited waveform. The middle plot illustrates the sampled waveform after the addition of amplitude noise. Although the signal was band-limited, the noise is not correlated to the trigger and therefore appears as very high frequency content. The bottom plot illustrates the effect of jitter on the sampled waveform. Jitter is also uncorrelated to the trigger and appears as high-frequency variations, however only introduces an error into the signal in the regions where the slope of the signal is non-zero. This is predominantly evident at the edges of the waveform.

This presents a challenge when applying waveform signal processing to equivalent-time sampled waveforms because the jitter and noise are not just undesirable artifacts, they are characteristics of the device being measured. As an example, consider a measurement case of applying a virtual equalizer to an equivalent-time waveform. It is desirable for the resulting processed waveform to have not just the correct deterministic shape (i.e. proper filtering of the signal components that are correlated to the trigger), but also the correct noise and jitter representation on the resulting waveform.

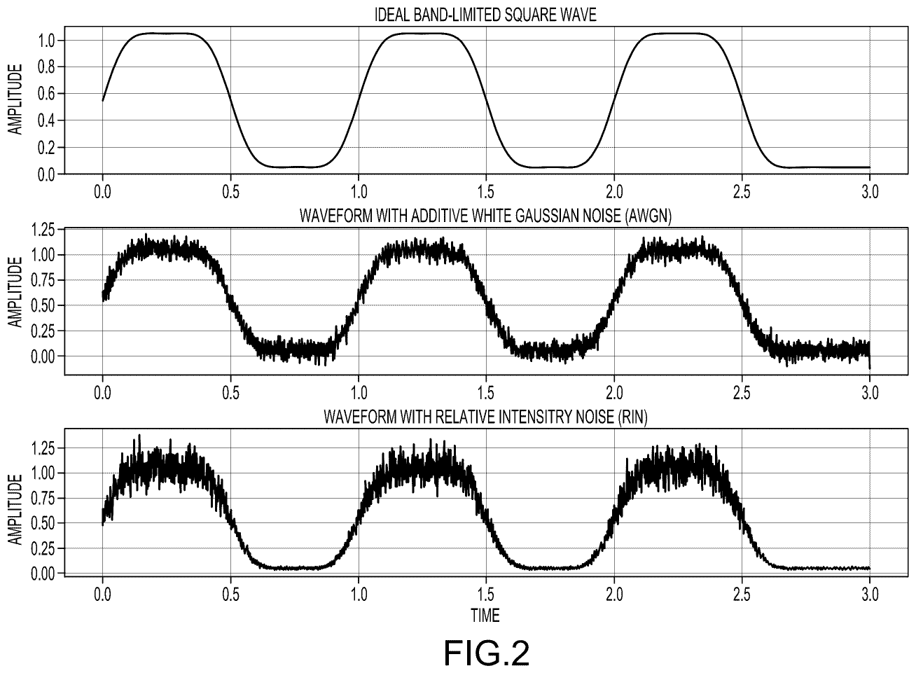

FIG. 2 illustrates examples of signal waveforms for reference in describing the effects of relative intensity noise (RIN) on equivalent-time waveforms. The top figure is an ideal band-limited waveform. The middle figure illustrates the effect of additive white noise. Note that the noise causes the same distortion on the “zero” and “one” levels of the square wave. The bottom figure illustrates the effect of laser RIN, which has a large effect on the “one” level of the signal but a small effect on the “zero” level. This is because the amplitude of RIN is proportional to the instantaneous laser power level.

Both jitter and RIN present a challenge to the intrinsic noise removal technique of previously referenced parent patent application Ser. No. 18/383,921 (published as U.S. Patent Publication No. 20250138073A1), as the noise variance is not constant across the waveform. The inventive concepts herein improve upon that noise removal technique by modeling the additive noise, jitter, and RIN across the waveform. The technique allows for the removal of the intrinsic noise and jitter of the sampling device while preserving the noise, jitter, and RIN present on the signal under test.

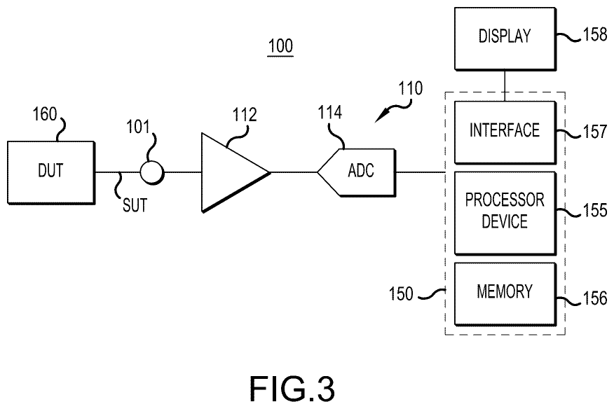

FIG. 3 is a simplified block diagram of a test system for making measurements of a signal under test (SUT), according to a representative embodiment. In the embodiments, the SUT is a repeating SUT. The test system may be configured to carry out the digital signal processing methods and include the software architecture for enhancing the fidelity of equivalent-time waveform measurements according to embodiments of the inventive concepts described herein.

As examples, the test system 100 may be an oscilloscope or a digital communication analyzer (DCA) having at least one input channel 110. Hereinbelow it is assumed for descriptive purposes that the test system 100 is an oscilloscope, but the inventive concepts are not limited in this fashion.

The oscilloscope 100 of the embodiments herein is an equivalent-time (sampling) oscilloscope. The input channel 110 includes a first port 101, an analog pre-processing circuit 112 and an analog-to-digital convertor (ADC) (or digitizer) 114. Generally, the analog pre-processing circuit 112 includes a combination of an attenuator, a dc offset circuit, and an amplifier which optimize the analog properties of a signal under test (SUT) for input the ADC 114.

The oscilloscope 100 receives the SUT output by a DUT 160 at a port of the channel 110, where the SUT may be generated by the DUT 160 or output by the DUT 160 in response to a stimulus signal. And, after pre-processing by the analog preprocessing circuit, the SUT is applied to the ADC 114 where it is repeatedly sampled and digitized.

The oscilloscope 100 further includes a processing unit 150 for processing the digitized SUT, performing various measurements, displaying waveforms of the SUT and/or measurement results, and controlling the processes performed by the oscilloscope 100, as discussed below.

The processing unit 150 includes a processor 155, memory 156, and an interface 157, for example, for interface with a display 158. The processor 155, together with the memory 156, implements the methods of enhancing the fidelity of equivalent-time waveform measurements discussed below. In various embodiments, the processor 155 may include one or more computer processors, digital signal processors (DSPs), field-programmable gate arrays (FPGAs), application specific integrated circuits (ASICs), or combinations thereof, using any combination of hardware, software, firmware, hard-wired logic circuits, or combinations thereof. The processor 155 may include its own processing memory (e.g., memory 156) for storing computer readable code (e.g., software, software modules) that enables performance of the various functions described herein. For example, the memory 156 may store software instructions/computer readable code executable by the processor 155 (e.g., computer processor) for performing some or all aspects of methods described herein.

References to the processor 155 may be interpreted to include one or more processing cores, as in a multi-core processor. The processor 155 may also refer to a collection of processors within a single computer system or distributed among multiple computer systems, as well as a collection or network of computing devices each including a processor or processors. Programs have software instructions performed by one or multiple processors that may be within the same computing device or which may be distributed across multiple computing devices.

The processing memory, as well as other memories and databases, are collectively represented by the memory 156, and may be random-access memory (RAM), read-only memory (ROM), flash memory, electrically programmable read-only memory (EPROM), electrically erasable and programmable read only memory (EEPROM), registers, a hard disk, a removable disk, tape, compact disk read only memory (CD-ROM), digital versatile disk (DVD), registers, a hard disk, a removable disk, tape, floppy disk, blu-ray disk, or universal serial bus (USB) driver, or any other form of storage medium known in the art, which are tangible and non-transitory storage media (e.g., as compared to transitory propagating signals). Memories may be volatile or non-volatile, secure and/or encrypted, unsecure and/or unencrypted, without departing from the scope of the present teachings. As mentioned above, the memory 156 is representative of one or more memories and databases, including the processing memory, as well as multiple memories and databases, including distributed and networked memories and databases.

The interface 157 may include a user interface and/or a network interface for providing information and data output by the processor 155 and/or the memory 156 to the user and/or for receiving information and data input by the user. That is, the interface 157 enables the user to enter data and to control or manipulate aspects of the process of measuring RF signals, and also enables the processor 155 to indicate the effects of the user's control or manipulation. The interface 157 may include one or more of ports, disk drives, wireless antennas, or other types of receiver circuitry. The interface 157 may further connect one or more user interfaces, such as a mouse, a keyboard, a mouse, a trackball, a joystick, a microphone, a video camera, a touchpad, a touchscreen, voice or gesture recognition captured by a microphone or video camera, for example, or any other peripheral or control to permit user feedback from and interaction with the processing unit 150.

The display 158 may be a monitor such as a computer monitor, a television, a liquid crystal display (LCD), an organic light emitting diode (OLED), a flat panel display, a solid-state display, or a cathode ray tube (CRT) display, or an electronic whiteboard, for example. The display 158 and/or the processor 155 may include one or more display interface(s), in which case the display 158 may provide a graphical user interface (GUI) for displaying and receiving information to and from a user.

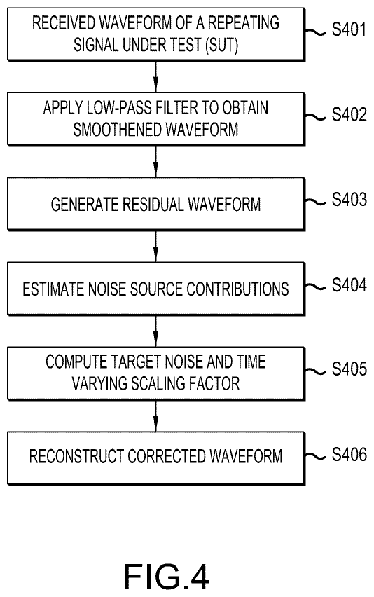

FIGS. 4 through 7 are flow diagrams for reference in describing methods for enhancing the fidelity of equivalent-time waveform measurements according to embodiments of the inventive concepts. As will become apparent below, the methods are characterized by modeling and compensating for multiple sources of distortion, including additive noise, timing jitter, and relative intensity noise (RIN). The methods operates on a digitized equivalent-time waveform of a repeating signal under test (SUT).

Referring to FIG. 4, at step S401 a digitized equivalent-time waveform W(t) of a repeating SUT is received. The waveform W(t) may be previously stored and retrieved from memory or generated in real-time by the measurement system (e.g., oscilloscope or analyzer).

Next, at step S402, the original equivalent-time waveform W(t) is passed through a low-pass filter to suppress high-frequency noise components. This results in a smoothed waveform S(t) which retains the deterministic structure of the signal while attenuating stochastic variations.

Then, at step S403, a residual waveform R(t) is calculated by subtracting the smoothed waveform from the original waveform:

$$R ( t ) = W ( t ) - S ( t )$$

This residual captures the non-deterministic components of the signal, including amplitude noise, jitter-induced distortion, and RIN.

At a subsequent step S404, noise source estimation using variance regression is carried out. Namely, the residual waveform R(t) is analyzed using a regression model that decomposes it into three components:
a. Additive noise: constant variance, σ²
b. Jitter-induced noise: variance proportional to the square of the derivative, (σ²ⱼ D(t)²
c. RIN-induced noise: variance proportional to the square of the signal level, σ²₁S(t)²
   where D(t) is a time derivative of the smoothed waveform S(t).

The regression model is of the form:

$${R ( t )}^{2} \approx {σ}_{n}^{2} + {σ}_{j}^{2} {D ( t )}^{2} + {σ}_{l}^{2} {S ( t )}^{2}$$

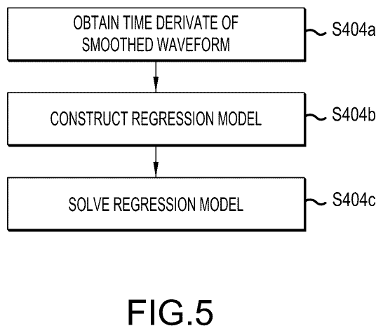

Attention is now directed to FIG. 5 for reference in describing an example of the estimation of the parameters σₙ, σⱼ, σₗ.

Referring to FIG. 5, at step S404a, the previously mentioned time derivative D(t) of the smoothed waveform S(t) is obtained:

$$D \underline{( t )} = \frac{d}{dt} S \underline{( t )}$$

This derivative signal may be used as a proxy for the waveform's local slope.

Although not shown in FIG. 5, the time derivative D(t) and the smoothed waveform S(t) may be normalized to unit maximums D-tilde(t) and S-tilde(t):

$$\tilde{D} ( t ) = \frac{D ( t )}{max D ( t )} , \tilde{S} ( t ) = \frac{S ( t )}{max S ( t )}$$

Still referring to FIG. 5, at step S404b, the regression model is constructed as follows:

$${R ( t )}^{2} = {β}_{0} + {β}_{1} {\tilde{D} ( t )}^{2} + {β}_{2} {\tilde{S} ( t )}^{2}$$

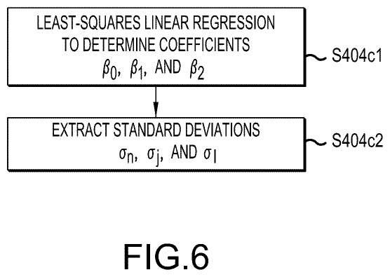

Next, at step S404c, the regression model is solved and standard deviations extracted. Namely, referring to FIG. 6, at step S404c1, the regression model is solved for β₀, β₁, β₂ using least-squares linear regression.

Then, at step S404c2 of FIG. 6, the standard deviations parameters an, (j and al are calculated as follows:

$${σ}_{n} = max ( {β}_{0} , 0 ) , {σ}_{j} = \frac{\sqrt{max ( {β}_{1} , 0 )}}{max D ( t )} , {σ}_{l} = \frac{\sqrt{max ( {β}_{2} , 0 )}}{max D ( t )}$$

This regression-based decomposition allows embodiments of the inventive concepts to quantify and later suppress the contributions of each noise source independently.

Next in the process is reconstruction of the final waveform with scaled residuals. This involves removing known intrinsic noise and jitter, where the method computes a scaling factor α(t) that adjusts the residuals.

Referring again to FIG. 4, at step S405, the target noise and jitter levels are computed after removing known intrinsic contributions:

$${σ}_{n}^{target} = \sqrt{max ( 0 , {σ}_{n}^{2} - {( {σ}_{n}^{int} )}^{2} )}$$

$${σ}_{j}^{target} = \sqrt{max ( 0 , {σ}_{j}^{2} - {( {σ}_{j}^{int} )}^{2} )}$$

And then the time varying scaling factor is computed as follows:

$$α ( t ) = \sqrt{\frac{{( {σ}_{n}^{target} )}^{2} + {( {σ}_{j}^{target} D ( t ) )}^{2} + {( {σ}_{l} S ( t ) )}^{2}}{{σ}_{n}^{2} + {( {σ}_{j} D ( t ) )}^{2} + {( {σ}_{l} S ( t ) )}^{2}}}$$

Next, at step S406, the corrected waveform is reconstructed as follows:

$${W}_{corrected} ( t ) = S ( t ) + α ( t ) \cdot R ( t )$$

This formulation enables selective suppression of known measurement-induced distortions while preserving signal-dependent noise such as RIN, resulting in a more accurate and physically meaningful waveform reconstruction

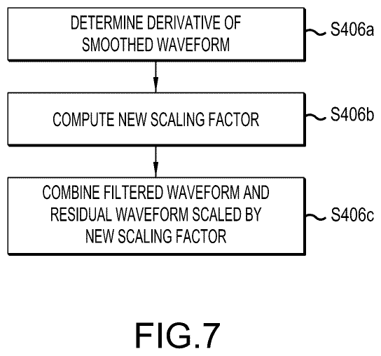

In some cases, referring to FIG. 7, the smoothed waveform S(t) may be further filtered to produce a modified version Sf(t). For example, this may be done to match a desired system response or to emulate a receiver.

Referring to FIG. 7, at step S40σₐ, the derivative Df(t) of the filtered waveform Sf(t) is computed as:

$${D}_{f} ( t ) = \frac{d}{dt} {S}_{f} ( t )$$

And then, at step S40σ_{b}, a new scaling factor is computed using the filtered waveform and its derivative as follows:

$${α}_{f} ( t ) = \sqrt{\frac{{( {σ}_{n}^{target} )}^{2} + {( {σ}_{j}^{target} {D}_{f} ( t ) )}^{2} + {( {σ}_{l} {S}_{f} ( t ) )}^{2}}{{σ}_{n}^{2} + {( {σ}_{j} D ( t ) )}^{2} + {( {σ}_{l} S ( t ) )}^{2}}}$$

Note that the numerator of the equation uses the derivative and amplitude of the filtered signal while the denominator uses the derivative and amplitude of the smoothed acquired signal. Finally, at step S40σ_{c}, the final reconstructed waveform is:

$${W}_{filtered} ( t ) = {S}_{f} ( t ) + {α}_{f} ( t ) \cdot R ( t )$$

This step allows the embodiments of the inventive concepts to incorporate additional signal conditioning while still compensating for noise, jitter, and RIN in a physically consistent manner.

While the disclosure has been particularly illustrated and described with reference to exemplary embodiments thereof, it will be appreciated by those of ordinary skill in the art that changes may be made therein without departing from the principles and spirit of the disclosure, the scope of which is defined in the appended claims and their equivalents. The exemplary embodiments should be considered in a descriptive sense only and not for purposes of limitation. Therefore, the scope of the disclosure is defined not by the detailed description of the disclosure but by the appended claims, and all differences within the scope will be construed as being included in the disclosure.

What is claimed is:

1. A digital signal processing method for enhancing fidelity of equivalent-time waveform measurements, comprising:
receiving a digitized equivalent-time waveform of a repeating signal under test (SUT);
applying a low-pass filter to the digitized equivalent-time waveform to obtain a smoothed waveform;
generating a residual waveform by subtracting the smoothed waveform from the digitized equivalent-time waveform;
estimating contributions of multiple noise sources in the residual waveform using a regression model;
computing target noise
$$( {σ}_{n}^{target} )$$
and jitter
$$( {σ}_{j}^{target} )$$
values by removing known intrinsic contributions; and
reconstructing a corrected waveform by combining the smoothed waveform with a scaled version of the residual waveform, wherein the scaling is based on the target noise source contributions.

2. The digital signal processing method of claim 1, wherein estimating contributions of multiple noise sources comprises:
calculating a time derivative of the smoothed waveform;
constructing a regression model relating the residual waveform to the smoothed waveform and its derivative; and
solving the regression model to estimate parameters corresponding to additive noise, jitter-induced noise, and relative intensity noise.

3. The digital signal processing method of claim 2, wherein the regression model is of the form:
$${R ( t )}^{2} \approx {σ}_{n}^{2} + {σ}_{j}^{2} {D ( t )}^{2} + {σ}_{l}^{2} {S ( t )}^{2}$$
where R(t) is the residual waveform, D(t) is the derivative of the smoothed waveform, S(t) is the smoothed waveform, σₙ represents additive noise, σⱼ represents jitter-induced noise, and σₗ represents relative intensity noise.

4. The digital signal processing method of claim 3, wherein solving the regression model comprises:
normalizing D(t) and S(t) to unit maximum;
performing least-squares linear regression to determine coefficients β₀, β₁, and β₂; and
extracting standard deviations σₙ, σⱼ, and σₗ from the coefficients.

5. The digital signal processing method of claim 1, wherein reconstructing the corrected waveform comprises:
computing a time-varying scaling factor α(t) based on the target noise source contributions; and
applying the scaling factor to the residual waveform before combining it with the smoothed waveform.

6. The digital signal processing method of claim 5, further comprising:
applying additional filtering to the smoothed waveform to produce a filtered waveform;
calculating a derivative of the filtered waveform; and
computing a new scaling factor based on the filtered waveform and its derivative.

7. The digital signal processing method of claim 6, wherein reconstructing the corrected waveform further comprises:
combining the filtered waveform with the residual waveform scaled by the new scaling factor to produce a filtered and corrected waveform.

8. A system for digital signal processing of equivalent-time waveforms, comprising:
an input interface configured to receive a digitized equivalent-time waveform of a repeating signal under test (SUT);
a processor configured to:
apply a low-pass filter to the digitized equivalent-time waveform to obtain a smoothed waveform,
calculate a residual waveform by subtracting the smoothed waveform from the digitized equivalent-time waveform,
estimate contributions of multiple noise sources in the residual waveform using a regression model, and
reconstruct a corrected waveform by combining the smoothed waveform with a scaled version of the residual waveform, wherein the scaling is based on the estimated noise source contributions; and
an output interface configured to output the corrected waveform.

9. The system of claim 8, wherein the processor is further configured to:
calculate a time derivative of the smoothed waveform;
construct a regression model relating the residual waveform to the smoothed waveform and its derivative; and
solve the regression model to estimate parameters corresponding to additive noise, jitter-induced noise, and relative intensity noise.

10. The system of claim 9, wherein the regression model is of the form:
$${R ( t )}^{2} \approx {σ}_{n}^{2} + {σ}_{j}^{2} {D ( t )}^{2} + {σ}_{l}^{2} {S ( t )}^{2}$$
where R(t) is the residual waveform, D(t) is the derivative of the smoothed waveform, S(t) is the smoothed waveform, σₙ represents additive noise, σⱼ represents jitter-induced noise, and σₗ represents relative intensity noise.

11. The system of claim 10, wherein solving the regression model comprises:
normalizing D(t) and S(t) to unit maximum;
performing least-squares linear regression to determine coefficients β₀, β₁, and β₂; and
extracting standard deviations σₙ, σⱼ, and σₗ from the coefficients.

12. The system of claim 8, wherein reconstructing the corrected waveform comprises:
computing a time-varying scaling factor α(t) based on the estimated noise source contributions; and
applying the scaling factor to the residual waveform before combining it with the smoothed waveform.

13. The system of claim 12, wherein the processor is further configured to:
apply additional filtering to the smoothed waveform to produce a filtered waveform;
calculate a derivative of the filtered waveform; and
compute a new scaling factor based on the filtered waveform and its derivative.

14. The system of claim 13, wherein reconstructing the corrected waveform further comprises:
combining the filtered waveform with the residual waveform scaled by the new scaling factor to produce a filtered and corrected waveform.

15. A non-transitory computer-readable medium storing instructions that, when executed by a processor, cause the processor to perform digital signal processing operations for enhancing fidelity of equivalent-time waveform measurements, the digital signal processing operations comprising:
receiving a digitized equivalent-time waveform of a repeating signal under test (SUT);
applying a low-pass filter to the digitized equivalent-time waveform to obtain a smoothed waveform;
generating a residual waveform by subtracting the smoothed waveform from the digitized equivalent-time waveform;
estimating contributions of multiple noise sources in the residual waveform using a regression model; and
reconstructing a corrected waveform by combining the smoothed waveform with a scaled version of the residual waveform, wherein the scaling is based on the estimated noise source contributions.

16. The non-transitory computer-readable medium of claim 15, wherein estimating contributions of multiple noise sources comprises:
calculating a time derivative of the smoothed waveform;
constructing a regression model relating the residual waveform to the smoothed waveform and its derivative; and
solving the regression model to estimate parameters corresponding to additive noise, jitter-induced noise, and relative intensity noise.

17. The non-transitory computer-readable medium of claim 16, wherein the regression model is of the form:
$${R ( t )}^{2} \approx {σ}_{n}^{2} + {σ}_{j}^{2} {D ( t )}^{2} + {σ}_{l}^{2} {S ( t )}^{2}$$
where R(t) is the residual waveform, D(t) is the derivative of the smoothed waveform, S(t) is the smoothed waveform, σₙ represents additive noise, σⱼ represents jitter-induced noise, and σₗ represents relative intensity noise.

18. The non-transitory computer-readable medium of claim 17, wherein solving the regression model comprises:
normalizing D(t) and S(t) to unit maximum;
performing least-squares linear regression to determine coefficients β₀, β₁, and β₂; and
extracting standard deviations σₙ, σⱼ, and σₗ from the coefficients.

19. The non-transitory computer-readable medium of claim 15, wherein reconstructing the corrected waveform comprises:
computing a time-varying scaling factor α(t) based on the estimated noise source contributions; and
applying the scaling factor to the residual waveform before combining it with the smoothed waveform.

20. The non-transitory computer-readable medium of claim 19, wherein the operations further comprise:
applying additional filtering to the smoothed waveform to produce a filtered waveform;
calculating a derivative of the filtered waveform;
computing a new scaling factor based on the filtered waveform and its derivative; and
combining the filtered waveform with the residual waveform scaled by the new scaling factor to produce a filtered and corrected waveform.
